(19) United States
(12) Patent Application Publication
(10) Pub. No.: US 2016/0064093 A1
(43) Pub. Date: Mar. 3, 2016

(54) SEMICONDUCTOR MEMORY DEVICE

(71) Applicant: KABUSHIKI KAISHA TOSHIBA, Tokyo (JP)

(72) Inventor: Takashi MAEDA, Kamakura Kanagawa (JP)

(21) Appl. No.: 14/637,287

(22) Filed: Mar. 3, 2015

(30) Foreign Application Priority Data
Sep. 3, 2014 (JP) 2014-179617

(51) Int. Cl. G11C 16/26

(52) U.S. Cl. CPC G11C 16/26

(57) ABSTRACT

A semiconductor memory device includes a memory cell, a bit line that is electrically connected to the memory cell, a first node that is electrically connected to the bit line, a capacitive element having a first end electrically connected to the first node and a second end electrically connected to a second node, and a transistor having a gate electrically connected to the first node, a first, and a second end, the second end being electrically connected to the second node.

### CROSS-REFERENCE TO RELATED APPLICATION

This application is based upon and claims the benefit of priority from Japanese Patent Application No. 2014-179617, filed Sep. 3, 2014, the entire contents of which are incorporated herein by reference.

### FIELD

Embodiments described herein relate generally to a semiconductor memory device.

### BACKGROUND

NAND type flash memories having, for example, memory cells stacked three-dimensionally, are known as semiconductor memory devices.

### DESCRIPTION OF THE DRAWINGS

FIG. 1 is a block diagram illustrating a semiconductor memory device according to a first embodiment.

FIG. 2 is a circuit diagram illustrating a memory cell array according to the first embodiment.

FIG. 3 is a circuit diagram illustrating a sense module according to the first embodiment.

FIG. 4 is a flow diagram illustrating a read operation according to the first embodiment.

FIG. 5 is a timing diagram illustrating various signals during the read operation according to the first embodiment.

FIG. 6 is a flow diagram illustrating a read operation according to a second embodiment.

FIG. 7 is a timing diagram illustrating various signals during the read operation according to the second embodiment.

FIG. 8 is a flow diagram illustrating a read operation according to a third embodiment.

FIG. 9 is a timing diagram illustrating various signals during the read operation according to the third embodiment.

FIG. 10 is a circuit diagram illustrating a sense module according to a fourth embodiment.

FIG. 11 is a timing diagram illustrating various signals during a read operation according to the fourth embodiment.

### DETAILED DESCRIPTION

The present embodiment now will be described more fully hereinafter with reference to the accompanying drawings, in which various embodiments are shown. In the drawings, the thickness of layers and regions may be exaggerated for clarity. Like numbers refer to like elements throughout. As used herein the term “and/or” includes any and all combinations of one or more of the associated listed items and may be abbreviated as “/”.

The terminology used herein is for the purpose of describing particular embodiments only and is not intended to limit the scope of the invention. As used herein, the singular forms “a,” “an” and “the” are intended to include the plurality of forms as well, unless the context clearly indicates otherwise. It will be further understood that the terms “comprises,” “comprising,” “having,” “includes,” “including” and/or variations thereof, when used in this specification, specify the presence of stated features, regions, steps, operations, elements, and/or components, but do not preclude the presence or addition of one or more other features, regions, steps, operations, elements, components, and/or groups thereof.

It will be understood that when an element such as a layer or region is referred to as being “on” or extending “onto” another element (and/or variations thereof), it may be directly on or extend directly onto the other element or intervening elements may also be present. In contrast, when an element is referred to as being “directly on” or extending “directly onto” another element (and/or variations thereof), there are no intervening elements present. It will also be understood that when an element is referred to as being “connected” or “coupled” to another element (and/or variations thereof), it may be directly connected or coupled to the other element or intervening elements may be present. In contrast, when an element is referred to as being “directly connected” or “directly coupled” to another element (and/or variations thereof), there are no intervening elements present.

It will be understood that, although the terms first, second, etc. may be used herein to describe various elements, components, regions, layers and/or sections, these elements, materials, regions, layers and/or sections should not be limited by these terms. These terms are only used to distinguish one element, material, region, layer or section from another element, material, region, layer or section. Thus, a first element, material, region, layer or section discussed below could be termed a second element, material, region, layer or section without departing from the teachings of the present invention.

Relative terms, such as “lower”, “back”, and “upper” may be used herein to describe one element's relationship to another element as illustrated in the Figures. It will be understood that relative terms are intended to encompass different orientations of the device in addition to the orientation depicted in the Figures. For example, if the structure in the Figure is turned over, elements described as being on the “backside” of substrate would then be oriented on “upper” surface of the substrate. The exemplary term “upper”, may therefore, encompasses both an orientation of “lower” and “upper,” depending on the particular orientation of the figure. Similarly, if the structure in one of the figures is turned over, elements described as “below” or “beneath” other elements would then be oriented “above” the other elements. The exemplary terms “below” or “beneath” may, therefore, encompass both an orientation of above and below.

Embodiments are described herein with reference to cross section and perspective illustrations that are schematic illustrations of idealized embodiments. As such, variations from the shapes of the illustrations as a result, for example, of manufacturing techniques and/or tolerances, are to be expected. Thus, embodiments should not be construed as limited to the particular shapes of regions illustrated herein but are to include deviations in shapes that result, for example, from manufacturing. For example, a region illustrated as flat may, typically, have rough and/or nonlinear features. Moreover, sharp angles that are illustrated, typically, may be rounded. Thus, the regions illustrated in the figures are schematic in nature and their shapes are not intended to illustrate the precise shape of a region and are not intended to limit the scope of the present invention.

A semiconductor memory device having an improvement in the reliability of data read is provided.

In general, according to one embodiment, a semiconductor memory device includes a memory cell, a bit line that is electrically connected to the memory cell, a first node that is electrically connected to the bit line, a capacitive element having a first end electrically connected to the first node and a second end electrically connected to a second node, and a transistor having a gate electrically connected to the first node, a first, and a second end, the second end being electrically connected to the second node.

The semiconductor memory device according to the embodiments will be described below with reference to the accompanying drawings. In the accompanying drawings, the same portions are denoted by the same reference numerals and signs. In addition, the repeated description thereof will be given as necessary.

### First Embodiment

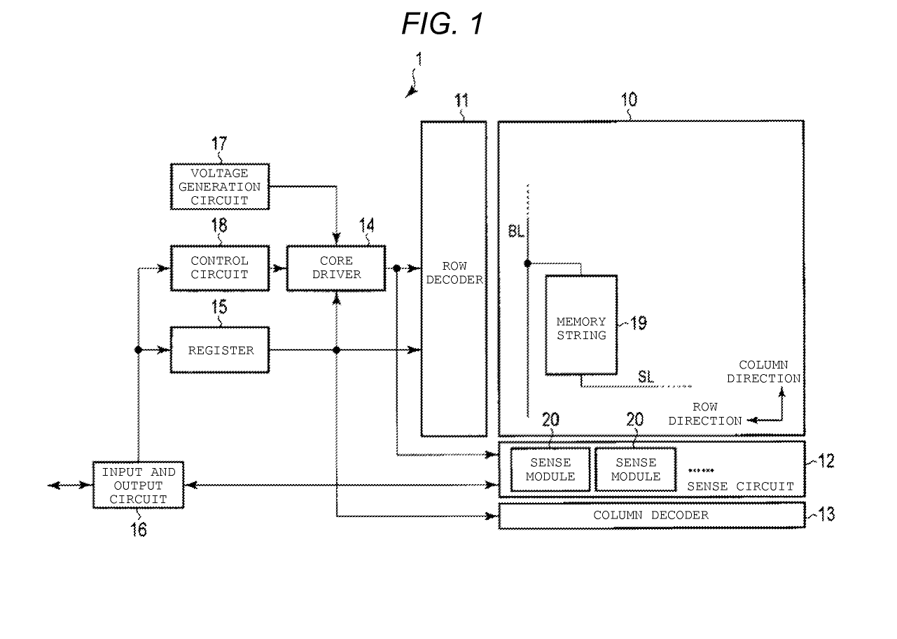

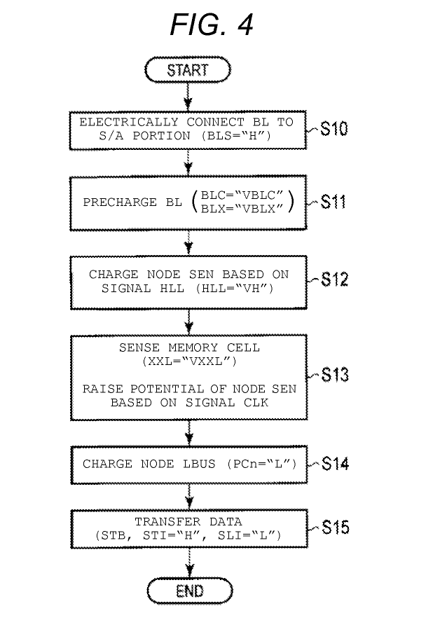

Hereinafter, the semiconductor memory device according to the present embodiment will be described with reference to FIGS. 1 to 5.

(1) Configuration of Semiconductor Memory Device

First, a configuration example of the semiconductor memory device according to the present embodiment will be described. In the following description, when simply referred to as “connection”, it means physical connection, and includes indirect connection through direct connection or other elements. When referred to as “electrical connection”, it means an electrical conduction state, and includes indirect connection through direct connection or other elements.

Outline Configuration Example of Semiconductor Memory Device

A NAND type flash memory 1 as the semiconductor memory device according to the present embodiment includes, for example, memory cells which are stacked three-dimensionally on a semiconductor substrate.

As illustrated in FIG. 1, the NAND type flash memory 1 includes a memory cell array 10, a row decoder 11, a sense circuit 12, a column decoder 13, a core driver 14, a register 15, an input and output circuit 16, a voltage generation circuit 17, and a control circuit 18.

The memory cell array 10 includes a plurality of memory strings 19. As described later, each of the memory strings 19 includes a plurality of memory cells. The memory cells are connected in series. A word line (not illustrated) is connected to the gate of the memory cell. In addition, one end of the memory string 19 is connected to a bit line BL, and the other end thereof is connected to a source line SL.

The row decoder 11 selects the row direction of the memory cell array 10. Specifically, the row decoder 11 selects any of word lines during writing and reading of data. In addition, the row decoder 11 applies a required voltage to the selected word line and a non-selected word line.

The sense circuit 12 includes a plurality of sense modules 20. Each of the sense modules 20 is provided for each bit line BL. The sense module 20 senses and amplifies read data in the bit line BL during reading of data. The sense module 20 transfers write data to the bit line BL during writing of data.

The column decoder 13 selects the column direction (Y direction) of the memory cell array 10. Specifically, the column decoder 13 selects any of the sense modules 20 during the transfer of write data and read data.

The voltage generation circuit 17 generates voltages required for writing, reading, and erasing of data, for example, in response to a command of the control circuit 18. The voltage generation circuit 17 supplies the generated voltage to the core driver 14.

The core driver 14 supplies a required voltage, supplied from the voltage generation circuit 17, to the row decoder 11 and the sense circuit 12, for example, in response to a command of the control circuit 18. The voltage supplied from the core driver 14 is transferred to the word line by the row decoder 11, and is applied to the bit line BL by the sense circuit 12.

The input and output circuit 16 controls the input and output of a signal to and from a controller or a host device that accesses the NAND type flash memory 1.

The register 15 holds a command, an address or the like which is received from the controller or the host device. In addition, the register 15 transfers, for example, a row address to the row decoder 11 and the core driver 14, and transfers a column address to the column decoder 13.

The control circuit 18 controls the operation of the entire NAND type flash memory 1 in accordance with the command which is received from the memory controller or the host device. Various control signals in the following description are generated by, for example, the control circuit 18.

Memory Cell Array

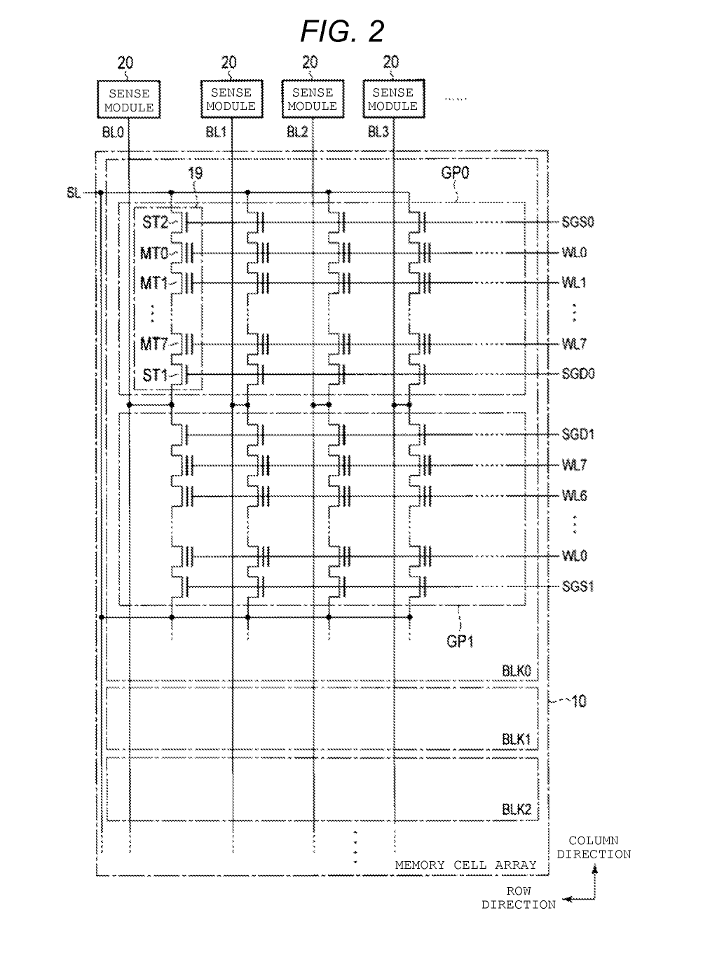

As illustrated in FIG. 2, the memory cell array 10 includes a plurality of blocks BLK (BLK0, BLK1, BLK2 . . . ). The individual block BLK is a set of the non-volatile memory cells. Each of the blocks BLK includes a plurality of memory groups GP (GP0, GP1, GP2 . . . ). The individual memory group GP includes a plurality of memory strings 19. The number of blocks within the memory cell array 10 and the number of memory groups within the block are arbitrary.

Each of the memory strings 19 includes, for example, eight memory cell transistors MT (MT0 to MT7) and selection gate transistors ST1 and ST2. However, the number of memory cell transistors MT may be 16, 32, 64, 128, and the like without being limited to 8, and may be any positive number. The memory cell transistor MT is provided with a stacked gate including a gate (hereinafter, also referred to as a control gate) which is a control node and a charge storage layer. The memory cell transistor MT functions as a memory cell, and may hold data in a non-volatile manner. The plurality of memory cell transistors MT are disposed between the selection gate transistors ST1 and ST2. The memory cell transistors MT are connected in series. One end of the memory cell transistor MT7 is connected to one end of the selection gate transistor ST1. One end of the memory cell transistor MT0 is connected to one end of the selection gate transistor ST2.

The gate of the selection gate transistor ST1 which is present in the memory group GPn is connected in common to a selection gate line SGDn. The gate of the selection gate transistor ST2 which is present in the memory group GPn is connected in common to a selection gate line SGSn (0≦n). The control gate of the memory cell transistor MTm which is present in the same memory group GP is connected in common to a word line WLm (0≦m≦7).

As described above, the memory strings 19 are disposed in a matrix configuration within the memory cell array 10. The memory strings 19 which are disposed in the same row in a column direction among the memory strings 19 are connected to the same bit line BL. That is, the bit line BL connects the memory strings 19 in common between a plurality of blocks BLK. In addition, the memory cell transistors MT which are disposed in a matrix configuration are connected in common to the source line SL.

Data of the memory cell transistors MT which are present in the same block BLK are erased collectively. However, data of the memory cell transistors MT may be erased collectively in units of the memory group GP or units of the memory string 19. On the other hand, reading and writing of data are collectively performed on a plurality of memory cell transistors MT which are connected in common to any of the word lines WL in any of the memory groups GP of any of the blocks BLK. This unit is referred to as a “page”.

As data which is capable of being held by the memory cell transistor MT (memory cell), there are binary values of, for example, “1” and “0”. When data of an on-state memory cell is read, a cell current (read current) flows in the memory cell. It is assumed that a current does not flow in an off-state memory cell, but in reality, an off-current (off leakage current) based on a leakage current may flow therein. Thus, an on-current is detected when the memory cell is turned on, an off-current is detected when the memory cell is turned off. The off-current is smaller than the on-current. Data which is held by the memory cell is identified depending on the magnitude of the detected current value.

Sense Circuit

The sense module 20 is provided, for example, on the semiconductor substrate, and immediately below the memory cell array 10.

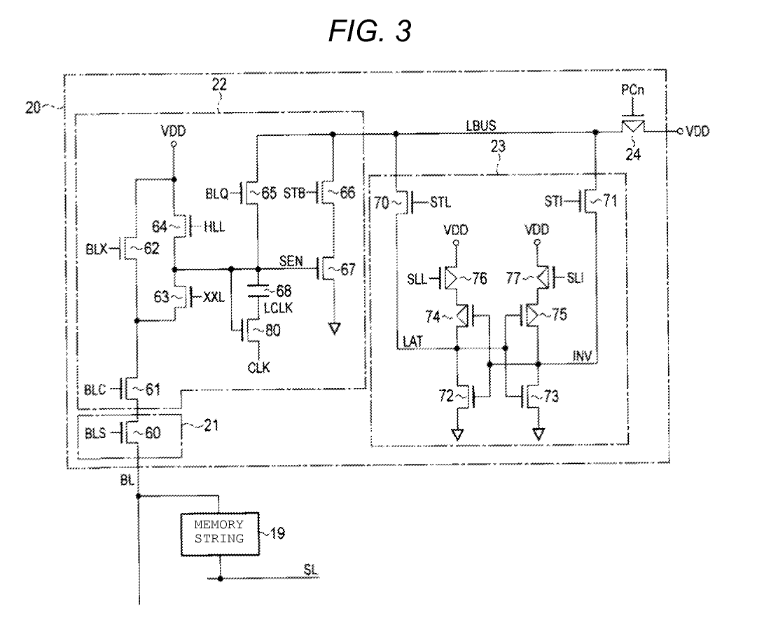

As illustrated in FIG. 3, the sense module 20 mainly includes a hookup unit 21, a sense amplifier 22, a data latch 23, and a transistor 24. The transistor 24 is, for example, a p-channel MOSFET (metal oxide semiconductor field effect transistor). In the following configuration, various control signals are provided by, for example, the aforementioned core driver 14.

The hookup unit 21 includes a transistor 60. The transistor 60 is, for example, an n-channel MOSFET. The transistor 60 receives a signal BLS in the gate, and is connected to the bit line BL at one end. The sense module 20 and the bit line BL are electrically connected or not connected to each other by turning on and turning off the transistor 60.

The sense amplifier 22 precharges (initially charges) the bit line BL during reading of data. In addition, the sense amplifier 22 senses and amplifies a current flowing in the bit line BL in accordance with data. The sense amplifier 22 includes a node SEN as a first node, a node LCLK as a second node, transistors 61 to 67 and 80, and a capacitive element 68. The transistors 61 to 67 and 80 are, for example, n-channel MOSFETs.

The transistor 61 receives a signal BLC in the gate, and is connected to the other end of the transistor 60 at one end. The transistor 61 controls a precharge potential of the bit line BL during reading of data. The transistor 62 receives a signal BLX in the gate, receives a power supply voltage VDD at one end, and is connected to the other end of the transistor 61 at the other end. The transistor 62 controls precharging of the bit line BL. The transistor 64 receives a signal HLL in the gate, receives the power supply voltage VDD in one end, and is connected to the node SEN at the other end. The transistor 64 controls charging of the node SEN. The transistor 63 receives a signal XXL in the gate, is connected to the node SEN at one end, and is connected to the other end of the transistor 61 at the other end. The transistor 63 controls discharging of the node SEN during data sensing.

When the state of the memory cell is sensed, the node SEN is electrically connected to the bit line BL. In addition, the node SEN is discharged at a different discharging rate in accordance with the state of the memory cell which is electrically connected to the bit line BL. Thereby, the node SEN is set at a potential according to a cell current flow through the bit line BL.

The transistor 67 as a first transistor senses the state of the memory cell through the node SEN and the bit line BL. Specifically, the transistor 67 is connected to the node SEN at the gate as a control node, and is connected to one end of the transistor 66 at one end. The other end of the transistor 67 is grounded. The transistor 67 senses whether read data is “0” or “1”. That is, the transistor 67 has a function of sensing the cell current, and is referred to as a sense transistor or the like.

The node LCLK as a second node is capacitively connected to the node SEN. That is, the node SEN and the node LCLK are connected to each other through the capacitive element 68.

The transistor 80 as a second transistor receives a signal CLK in one end, is connected to the node LCLK at the other end, transfers the signal CLK to the node LCLK, and is connected to the node SEN at the gate. The transistor 80 is turned on or turned off in accordance with the potential of the node SEN. When the memory cell is sensed, the signal CLK is further transferred from the node LCLK to the node SEN, and raises the potential of the node SEN.

The transistor 65 receives a signal BLQ at the gate, is connected to the node SEN at one end, and is connected to a node LBUS at the other end. The transistor 65 controls, for example, the charging and discharging of the node SEN. The node LBUS connects the sense amplifier 22 and the data latch 23. The transistor 66 receives a signal STB at the gate, is connected to the node LBUS at the other end, and controls the storage of read data in the data latch 23.

The data latch 23 holds read data which is sensed and amplified in the sense amplifier 22. The data latch 23 includes transistors 70 to 73, and transistors 74 to 77. The transistors 70 to 73 are, for example, n-channel MOSFETs. The transistors 74 to 77 are, for example, p-channel MOSFETs.

The transistors 72 and 74 forma first inverter, of which the output node is a node LAT, and of which the input node is a node INV. The transistors 73 and 75 form a second inverter, of which the output node is a node INV, and of which the input node is a node LAT. The data latch 23 holds data by the first and second inverters.

That is, the transistor 72 is connected to the node INV at the gate, and is connected to the node LAT at one end. The other end of the transistor 72 is grounded. The transistor 73 is connected to the node LAT at the gate, and is connected to the node INV at one end. The other end of the transistor 73 is grounded. The transistor 74 is connected to the node INV at the gate, is connected to the node LAT at one end, and is connected to one end of the transistor 76 at the other end. The transistor 75 is connected to the node LAT at the gate, is connected to the node INV at one end, and is connected to one end of the transistor 77 at the other end.

The transistor 76 receives the power supply voltage VDD in the other end, and receives a signal SLL in the gate. The transistor 76 controls an enable operation of the first inverter. The transistor 77 receives the power supply voltage VDD at the other end, and receives a signal SLI in the gate. The transistor 77 controls an enable operation of the second inverter.

The transistors 70 and 71 control the input and output of data to and from the first and second inverters. The transistor 70 is connected to the node LBUS at one end, and is connected to the node LAT at the other end. The transistor 70 receives a signal STL in the gate. The transistor 71 is connected to the node LBUS at one end, and is connected to the node INV at the other end. The transistor 71 receives a signal STI in the gate.

The transistor 24 receives the power supply voltage VDD in one end, is connected to the node LBUS at the other end, and receives a signal PCn in the gate. The transistor 24 controls charging of the node LBUS to the power supply voltage VDD.

(2) Data Read Method of Semiconductor Memory Device

Next, a read operation of data in the NAND type flash memory 1 as a semiconductor memory device will be described. In the following description, a memory cell to be read is also referred to as a selected memory cell. In addition, for example, the block BLK including the selected memory cell, or the like is also referred to as a selected block BLK or the like, and a block BLK which does not include the selected memory cell, or the like is also referred to as a non-selected block BLK or the like.

Outline of Read Operation

First, the voltage generation circuit 17 generates voltages VCGRV, VREAD, VSG, and VBB. The voltage VCGRV is a voltage to be applied to a selected word line, and is a voltage according to data (threshold level) desired to be read. The voltage VREAD is a voltage for turning on the memory cell transistor regardless of data held therein (VREAD>VCGRV). The voltage VSG is a voltage for turning on the selection transistors ST1 and ST2 (VREAD>VSG). The voltage VBB is a voltage for turning off the selection transistors ST1 and ST2, and is, for example, a negative voltage, 0 V or the like (VSG>VBB).

The core driver 14 applies VSS (e.g., ground potential, 0 V) to the source line SL of the memory cell array 10. The core driver 14 applies a clamp voltage to the bit line BL through the sense circuit 12. The row decoder 11 dividedly transfers various voltages from the voltage generation circuit 17 as signals to each portion of the memory cell array 10.

Specifically, the core driver 14 applies the voltage VCGRV to the selected word line within the selected block BLK through the row decoder 11. The core driver 14 applies the voltage VREAD to the non-selected word line within the selected block BLK.

The core driver 14 applies the voltage VSG to the selection gate lines SGD and SGS through the row decoder 11 with respect to the selected memory string 19 within the selected block BLK. The core driver 14 applies the voltage VBB to the selection gate lines SGD and SGS with respect to the non-selected memory string 19 within the selected block BLK.

In the non-selected block BLK, the word line WL is an electrically floating state. The core driver 14 applies the voltage VBB to the selection gate lines SGD and SGS through the row decoder 11. Alternatively, the core driver 14 may apply VSS to the selection gate lines SGD and SGS. The selection gate lines SGD and SGS may be electrically floating state.

As described above, the voltage VCGRV is applied to the control gate of the selected memory cell, of which one end and the other end are electrically connected to the bit line BL and the source line SL, respectively. An on-current or an off-current flows from the bit line BL to the source line SL in accordance with the on-off state of the selected memory cell. This current is detected by the sense module 20, and thus the read operation is performed.

Operation of Sense Module

The core driver 14 sets the signal BLS to be at a “H” level, and electrically connects the sense module 20 and the bit line BL (step S10). The node INV is reset, and is set to be at an “L” level.

In addition, the core driver 14 precharges the bit line BL (step S11). That is, the core driver 14 raises the potentials of the signals BLC and BLX which are VSS until then to VBLC and VBLX, respectively (time t0). The voltage VBLC is a voltage for determining the transfer amount of a bit line voltage. The bit line voltage is changed to a voltage VBL which is clamped by the voltage VBLC. Thereby, the bit line BL is precharged by the voltage VDD through the transistors 60 to 62. The signals BLC and BLX are maintained at the voltages VBLC and VBLX until time t11 after the storage of data in the data latch 23 is terminated.

Next, the core driver 14 charges the node SEN based on of the signal HLL (step S12). That is, the core driver 14 raises the potential of the signal HLL to VH (time t1). Thereby, the transistor 64 is turned on, and the node SEN is charged to the voltage VDD. The voltage VH is a voltage which enables the transistor 64 to transfer the voltage VDD. The node SEN is set at the potential VDD, and thus the transistors 67 and 80 are turned on. The charging of the node SEN is performed until time t2.

For example, the voltage VH of the signal HLL may be set to a value depending on the threshold voltage for turning on and off the transistors 64 and 67. Thereby, the influence of a variation in threshold voltage for each transistor is alleviated, and thus the operations of the transistors 64 and 67 may be performed more reliably. Specifically, the above voltage VH may be set to, for example, a value proportional to the sum of the transistors 64 and 67.

Next, the core driver 14 senses the state of the memory cell through the sense module 20 (step S13). That is, the core driver 14 raises the potential of the signal XXL to VXXL (time t3). Thereby, the transistor 63 is turned on, and the node SEN is electrically connected to the bit line BL. Thus, an on-current or an off-current flows from the node SEN through the bit line BL to the source line SL. Electrical connection between the node SEN and the bit line BL is maintained until time t6.

In addition, the core driver 14 raises the potential of the node SEN based on the signal CLK (step S13). That is, the core driver 14 raises the potential of the signal CLK (time t3). Thereby, the potential of the node LCLK is boosted through the transistor 80 which is turned on. In addition, the potential of the node SEN is boosted through the capacitive element 68. The signal CLK continues to rise until time t5, and is also maintained at a high potential after time t6.

Because of the rise in the potential of the signals XXL and CLK, the potential of the node SEN rises with a rise in the signal CLK, and is reduced by a cell current flowing from the node SEN to the source line SL. Thus, the behavior of a potential in the node SEN varies depending on the magnitude of the cell current. When the selected memory cell is turned on (thick line), a relatively large current (on-current) flows from the node SEN to the source line SL. For this reason, the potential of the node SEN rises until time t4, but thereafter, drops due to the transistor 80 being turned off. When the selected memory cell is turned off (thin line), only a small current (off-current) flows from the node SEN to the source line SL. For this reason, the transistor 80 is not turned off, and the potential of the node SEN continues to rise with a rise in the potential of the node LCLK.

More specifically, when the transistor 80 is turned on, the potential of the node SEN rises due to coupling with the potential of the node LCLK, regardless of the state of the selected memory cell. However, since the turning on of the selected memory cell leads to a large flowing current (on-current), a rise in the potential of the node SEN is gentle. Alternatively, when the cell current is set to a large value, or the like, the node discharging speed of the node SEN due to the current becomes faster than the node charging speed due to the coupling. Therefore, the potential of the node SEN starts to drop after time t3 without the rise in the potential. In any case, a difference due to the on-off state of the selected memory cell occurs in the potential of the node SEN. In the drawing, a difference in the potential of the node SEN occurring due to a difference in the state of the selected memory cell is illustrated as (b). The node SEN when the transistor 80 is turned on mainly has an apparent capacitance (Csen+Csenp) obtained by adding a capacitance Csen of the capacitive element 68 to a parasitic capacitance Csenp of the transistors 63 to 65 and 67 which are connected to the node SEN and an adjacent wiring of the node SEN, or the like.

Thereafter, when the selected memory cell is turned on, a difference between the potential of the node SEN and the potential of the node LCLK gradually decreases due to the flow of a large cell current. When this difference is lower than the threshold voltage Vth of the transistor 80 (VSEN-VLCLK<Vth), the transistor 80 is turned off (time t4). Thereby, since the node LCLK is set to be in a floating state and has no influence on the node SEN, a rise in the potential of the node SEN is stopped. Thus, after time t4, the potential of the node SEN is discharged at a greater rate than before time t4 due to discharge based on the cell current (time t6). In the drawing, the level of a drop in the potential of the node SEN due to no contribution of the signal CLK is illustrated as (c).

In addition, when the transistor 80 is turned off, the apparent capacitance of the node SEN becomes smaller than the above capacitance (Csen+Csenp). A capacitance Csen×Clclk/(Csen+Clclk) of the capacitive element 68 which is connected in series to the node LCLK in a floating state, where Clclk is the capacitance of the node LCLK, is sufficiently smaller than the capacitance Csen. That is, an apparent capacitance (Csen×Clclk/(Csen+Clclk)+Csenp) of the node SEN when the transistor 80 is turned off is smaller than the above capacitance when the transistor 80 is turned on (Csen×Clclk/(Csen+Clclk)+Csenp<Csen+Csenp).

In this manner, the apparent capacitance of the node SEN becomes smaller, and thus discharge due to the cell current is also accelerated. In addition, when a rise in the signal CLK is stopped, the potential of the node SEN slightly drops regardless of the state of the selected memory cell. When the selected memory cell is turned on, the apparent capacitance of the node SEN becomes smaller. Therefore, in this case, the turning on of the selected memory cell also leads to a large drop in the potential of the node SEN. In the drawing, the level of a drop in the potential of the node SEN due to a drop in the apparent capacitance of the node SEN is illustrated as (d).

On the other hand, when the selected memory cell is turned off, only a small cell current flows, and thus a potential difference between the node SEN and the node LCLK is maintained to be equal to or higher than the threshold voltage Vth of the transistor 80. For this reason, the transistor 80 is not turned off, and the potential of the node SEN is maintained to be equal to or higher than VDD. Therefore, for example, a difference (a) obtained by adding (b), (c), and (d) together occurs in the potential of the node SEN, depending on the on-off state of the selected memory cell.

As described above, when the potential of the node SEN is maintained to be equal to higher than the threshold voltage Vth of the transistor 67 (SEN=“H”), the transistor 67 which is a sense transistor is maintained to be turned on. When the potential of the node SEN drops to less than the threshold voltage Vth of the transistor 67 (SEN=“L”), the transistor 67 is turned off.

Next, the core driver 14 charges the node LBUS (step S14). That is, the core driver 14 sets the signal PCn to be at an “L” level (time t7). Thereby, the transistor 24 is turned on, and the node LBUS is charged to VDD. The charging of the node LBUS is performed until time t8.

Subsequently, the core driver 14 transfers data to the data latch 23 (step S15). That is, the core driver 14 sets the signals SLI, STI, and STB to be at an “H” level (time t9). Thereby, the transistors 66 and 71 are turned on, and the transistor 77 is turned off. When the transistor 67 which is a sense transistor is turned on (SEN=“H”), the node LBUS is discharged to approximately VSS, and an “L” level is stored in the node INV of the data latch 23. When the transistor 67 is turned off (SEN=“L”), the potential of the node LBUS maintains approximately VDD, and an “H” level is stored in the node INV. The signals SLI, STI, and STB are maintained to be at each level until the storage of data in the data latch 23 is terminated (time t10).

(3) Effect According to the Present Embodiment

According to the present embodiment, the following one or a plurality of effects are exhibited.

(A) According to the present embodiment, the NAND type flash memory 1 includes the transistor 80. The transistor 80 receives the signal CLK in one end, is connected to the node LCLK at the other end, and is connected to the node SEN at the gate. Thereby, the transistor 80 is switched on or off in accordance with the potential of the node SEN during reading of data. Thus, it is possible to increase an on/off ratio during data reading.

As described above, a difference in the potential of the node SEN due to a difference in the state of the memory cell may become smaller in the NAND type flash memory, along with a reduction in the size of memory cell, or the like. This is because, an on-current may be not only reduced due to a reduction in the size of the memory cell, but also an off leakage current may increase due to an increase in the number of memory cells which are connected to one bit line.

In addition, a lower limit based on a variation or the like in the set voltage of the source line and the bit line or in the threshold voltage of each transistor is present in the potential of the node SEN. A difference between the potential of the initial charging level of the node SEN and the potential in the lower limit of the node SEN may also be reduced due to the above reduction in the size. Based on the factors, in the NAND type flash memory, the read accuracy of data from the memory cell may be deteriorated, or data may not be able to be read.

In the present embodiment, the sense amplifier 22 includes the transistor 80, thereby allowing the on/off ratio during data reading to be increased.

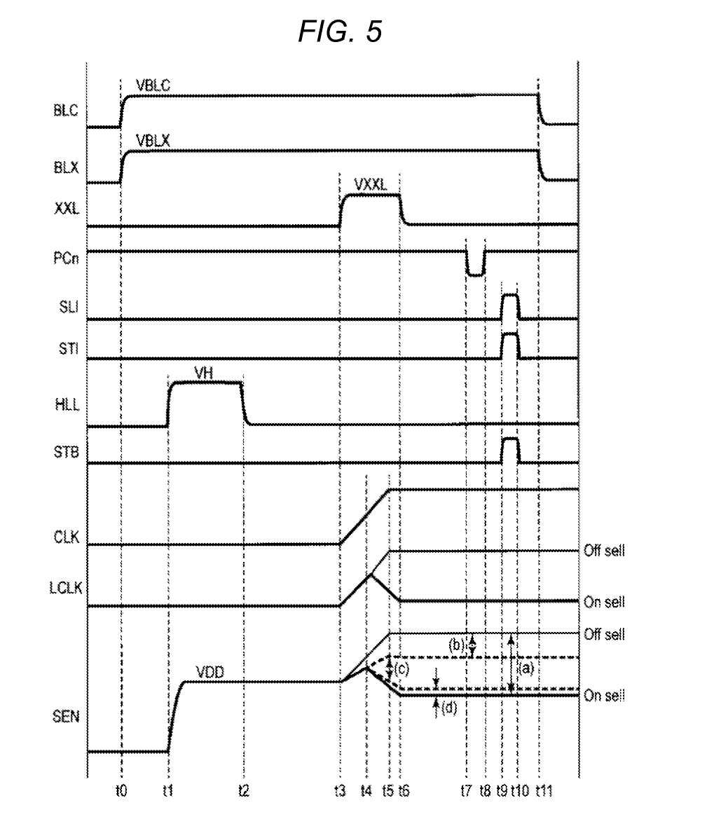

(B) According to the present embodiment, the sense amplifier 22 includes the transistor 80, thereby allowing the on/off ratio to be increased by a difference (c) in FIG. 5.

That is, when the potential difference between the node SEN and the signal CLK is less than a certain value, the transistor 80 is turned off, and the transfer of the signal CLK to the node LCLK is stopped. Specifically, when the selected memory cell is turned on, the discharging rate of node SEN becomes faster, and the potential difference between the node SEN and the node LCLK becomes less than the threshold voltage Vth of the transistor 80. Meanwhile, the potential of the node LCLK is the same as the potential of the signal CLK until the transistor 80 is turned off. Due to the above reduction in the potential difference, the transistor 80 is turned off, and the transfer of the signal LCK to the node LCLK is stopped. Thereby, when the selected memory cell is turned on, a rise in the potential of the node SEN due to the signal CLK is stopped, and thus the discharging of the node SEN due to an on-current may be promoted.

In addition, when the potential difference between the node SEN and the signal CLK is equal to or greater than a certain value, the transistor 80 is turned on, and the transfer of the signal CLK to the node LCLK is performed. Specifically, when the selected memory cell is turned off, the discharging rate of the node SEN becomes slower, and the potential difference between the node SEN and the node LCLK is maintained to be equal to or higher than the threshold voltage Vth of the transistor 80. Meanwhile, since the transistor 80 is turned on, the potential of the node LCLK is the same as the potential of the signal CLK. In such a case, the transistor 80 is maintained to be turned on, and thus the transfer of the signal LCK to the node LCLK is continued. Thereby, when the selected memory cell is turned off, a rise in the potential of the node SEN due to the signal CLK is continued, and thus it is possible to suppress a drop in the potential of the node SEN due to an off leakage current.

In this manner, the difference (c) includes a difference due to no contribution of the signal CLK when the selected memory cell is turned on, and a difference due to the continuation of supply of the signal CLK when the selected memory is turned off.

Thus, in the present embodiment, as illustrated in FIG. 5, when the selected memory cell is turned on, the potential of the node SEN drops by the difference (c) due to no contribution of the signal CLK.

(C) According to the present embodiment, the sense amplifier 22 includes the transistor 80, thereby allowing the on/off ratio to be increased by a difference (d) in FIG. 5.

As described above, when the potential difference between the node SEN and the node LCLK becomes less than the threshold voltage Vth of the transistor 80, the transistor 80 is turned off. Thereby, the node LCLK is set to be in a floating state, and thus the apparent capacitance of the node SEN becomes smaller than that when the transistor 80 is turned on, which leads to the discharging of the node SEN being accelerated.

Thus, as illustrated in FIG. 5, when the selected memory cell is turned on, the potential of the node SEN drops by the difference (d) due to the acceleration of discharging along with a drop in the apparent capacitance of the node SEN.

(D) According to the present embodiment, the sense amplifier 22 includes the transistor 80, and thus a difference in the potential of the node SEN due to a difference in the state of the selected memory cell increases to the difference (a) in FIG. 5. That is, the on/off ratio during data reading increases.

(E) According to the present embodiment, the core driver 14 senses the state of the memory cell through the node SEN in a state where the signal CLK is maintained at a high potential. Therefore, a potential during initial charging of the node SEN is not required to be set to a high potential. Specifically, the potential during initial charging of the node SEN may be reduced to, for example, approximately the threshold voltage Vth of the transistor 67, or approximately the lower limit of the node SEN. Thus, a reduction in power consumption may be achieved.

(F) According to the present embodiment, the transistor 80 continues to receive the signal CLK even after the memory cell is sensed. In this manner, the core driver 14 maintains the signal CLK to a high potential until the signal XXL is dropped to VSS, and continues to provide the signal CLK even after that. Thereby, even when the selected memory cell is turned off, the node SEN may be continuously maintained at a high potential by suppressing the influence of an off leakage current. That is, it is possible to maintain the difference (c) in FIG. 5. Thus, the margin of a data reading operation increases.

(4) Modification Example According to the Present Embodiment

As a modification example of the present embodiment, a configuration example in which a variation in the threshold voltage of the transistor 80 is suppressed will be described below.

In transistor 80, a variation may occur in the threshold voltage thereof due to a temperature under the environment where the transistor 80 is disposed, a process variation during the formation of the transistor 80, or the like. As described above, when the selected memory cell is turned on, a timing at which the transistor 80 is turned off is directly influenced by a variation in the threshold voltage of the transistor 80. Thereby, the magnitude of an on/off ratio which is finally obtained is also influenced.

In order to reduce such an influence of a variation in the threshold voltage of the transistor 80, for example, the potential during initial charging of the node SEN may be preferably caused to depend on the threshold voltage Vth of the transistor 80. Specifically, during initial charging of the node SEN, for example, the voltage VH of the signal HLL is adjusted so that the node SEN is set to be a potential proportional to “+Vth”.

As described above, it is possible to prevent a timing at which the transistor 80 is turned off from varying due to a variation in the threshold voltage of the transistor 80. Thus, it is possible to stabilize data reading, and to increase a reading margin.

### Second Embodiment

The present embodiment is different from that in the above-mentioned embodiment, in that a rise in the signal CLK is started before the sensing of the memory cell is started.

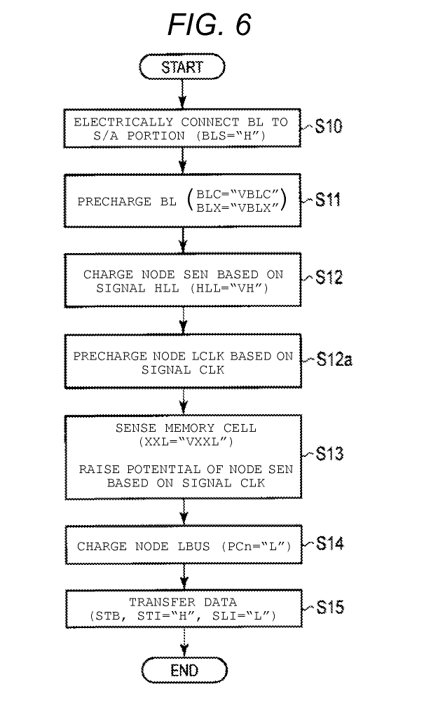

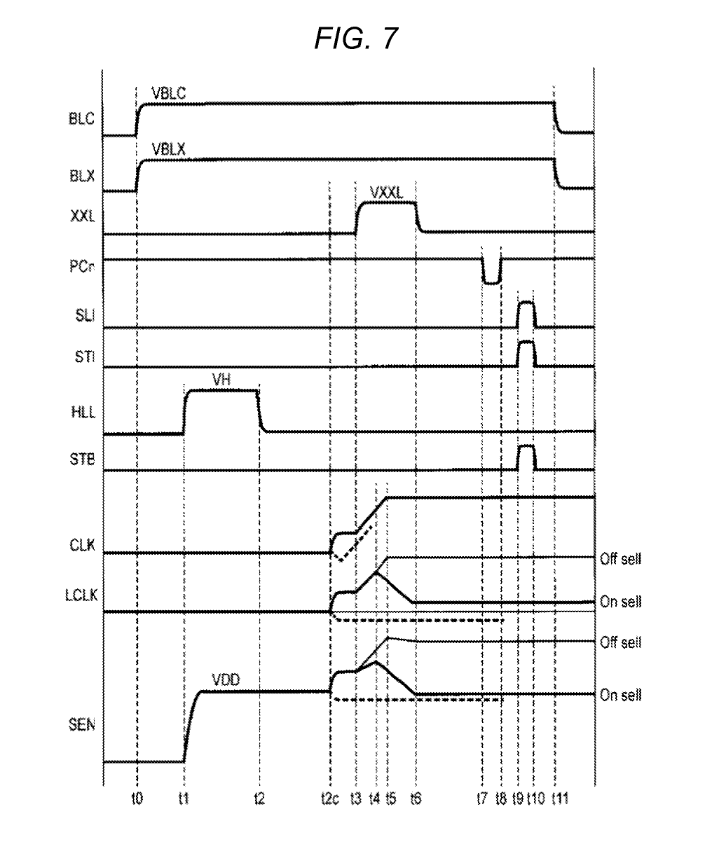

A configuration example of a semiconductor memory device according to the present embodiment will be described with reference to FIGS. 6 and 7.

As illustrated in FIG. 6, the core driver 14 similar to that in FIG. 1 stated above charges the node SEN as a first node through a signal HLL (step S12), and then precharges the node LCLK as a second node based on the signal CLK (step S12a). That is, as illustrated in FIG. 7, the core driver 14 sets the potential of the signal CLK to VSS or higher and any potential lower than a potential during sensing (time t2c). Thereby, the node SEN is charged to a value which is higher than the voltage VDD and is lower than the potential during sensing. Thereafter, similarly to the above-mentioned embodiment, the core driver 14 senses the state of the memory cell while further raising the potential of the node SEN based on the signal CLK (step S13).

When the cell current is set to a large value, or the like, for example, when data of the selected memory cell which is turned on is sensed, the potential of the node SEN may go close to the lower limit immediately after the discharging of the node SEN is started (dotted lines in the drawing). In this case, there is a concern that the potential of the signal CLK or the potential of the node LCLK may be deflected to the negative side, by coupling from the node SEN, before the potential rises sufficiently (dotted lines in the drawing).

Consequently, according to the present embodiment, the core driver 14 raises the potential of the signal CLK before the start of sensing, and precharges the node LCLK. Thereby, in addition to the effects of the above-mentioned embodiment, it is possible to prevent the potentials of the signal CLK and the node LCLK from being deflected to the negative side.

### Third Embodiment

The present embodiment is different from that in the above-mentioned embodiment, in that a rise in the signal CLK is started before the initial charging of the node SEN as a first node is started.

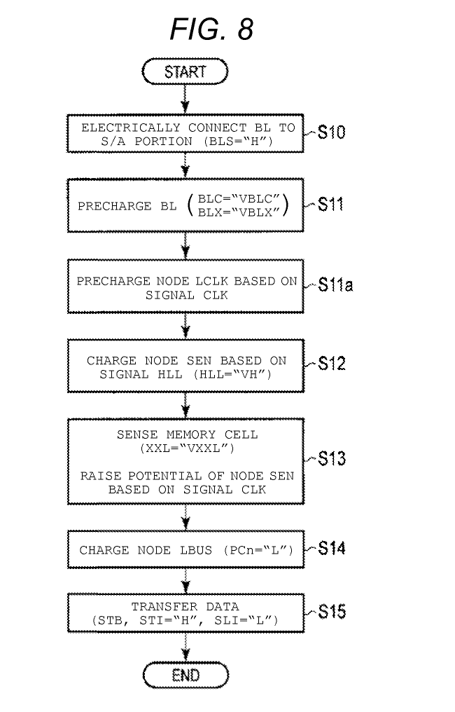

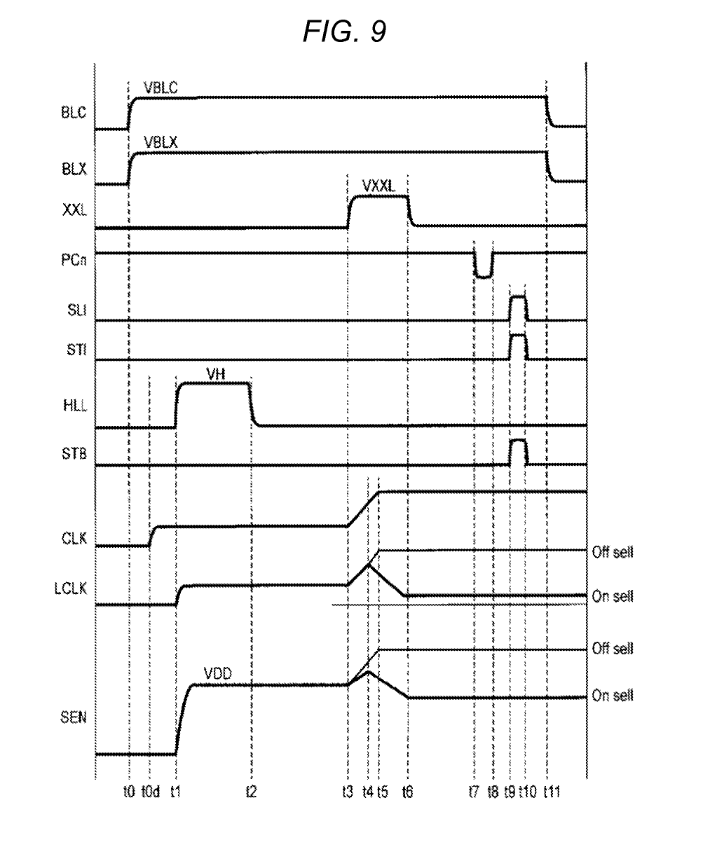

A configuration example of a semiconductor memory device according to the present embodiment will be described with reference to FIGS. 8 and 9.

As illustrated in FIG. 8, the core driver 14 similar to that in FIG. 1 stated above precharges the node LCLK as a second node based on of the signal CLK before the node SEN is charged based on of the signal HLL (step S12) (step S11a). That is, as illustrated in FIG. 9, the core driver 14 sets the potential of the signal CLK to VSS or higher and any potential which is lower than the potential during sensing (time tOd). At this point in time, since the transistor 80 is turned off, a rise in the potential of the node LCLK due to the signal CLK does not occur. When the core driver 14 starts to precharge the node SEN at time t1, the transistor 80 is turned on, and the node LCLK is precharged up to the same potential as that of the signal CLK. Thereafter, similarly to the above-mentioned embodiment, the core driver 14 senses the state of the memory cell while further raising the potential of the node SEN based on of the signal CLK (step S13).

When data of the selected memory cell which is turned on is sensed, the transistor 80 is preferably turned off, for example, at a point in time as early as possible during a sensing period. This is because, the start timing of a drop in the potential of the node SEN is moved up, and thus it is possible to secure a sufficient on/off ratio more reliably, and to shorten a sensing time.

Consequently, according to the present embodiment, the core driver 14 raises the potential of the signal CLK before the charging of the node SEN is started, and precharges the node LCLK. Thereby, in addition to the effects of the above-mentioned embodiment, it is possible to reduce a potential difference between the signal CLK and the node LCLK, and the node SEN before the start of sensing. Thus, after sensing is started, a time to wait for a rise in the signal CLK and the potential of the node LCLK is shortened, and thus it is possible to turn off the transistor 80 earlier. Thus, it is possible to shorten a sensing time. In addition, it is possible to secure a sufficient on/off ratio more reliably.

Further, in this case, the potential based on the precharge of the node LCLK may be set to a potential proportional to “−Vth” so as to depend on the threshold voltage Vth of the transistor 80. When the discharging rates of the node SEN are equal to each other, and the cell current flows by the same extent, a difference between a voltage of the node LCLK by which the transistor 80 is turned off based on precharge proportional to “−Vth” stated above and an initial voltage of the node LCLK becomes substantially constant regardless of a fluctuation in threshold voltage due to a process, a temperature or the like. That is, the threshold voltage Vth is not involved in a timing at which the transistor 80 is turned off, and thus the influence of a variation in the threshold voltage of the transistor 80 may also be reduced.

Meanwhile, it is also possible to control a timing at which the transistor 80 is turned off, for example, by adjusting the rising rate of the signal CLK (rising rate of the potential of the signal CLK). That is, when the rising rate of the signal CLK is made higher, a timing at which the transistor 80 is turned off may be made faster. When the rising rate of the signal CLK is made lower, a timing at which the transistor 80 is turned off may be made slower. In this manner, the rising rate of the signal CLK may be adjusted instead of the precharge of the node LCLK, or in addition thereto.

Meanwhile, the adjustment of the precharge and the rising rate of the node LCLK may be achieved, for example, without increasing a power supply voltage. It is also not likely to obstruct an achievement in constant voltage.

### Fourth Embodiment

In the above-mentioned embodiment, an example is described in which the sense amplifier 22 of a current sensing type is used. In the present embodiment, an example will be described in which a sense amplifier of a voltage sensing type is used.

(1) Configuration of Sense Circuit

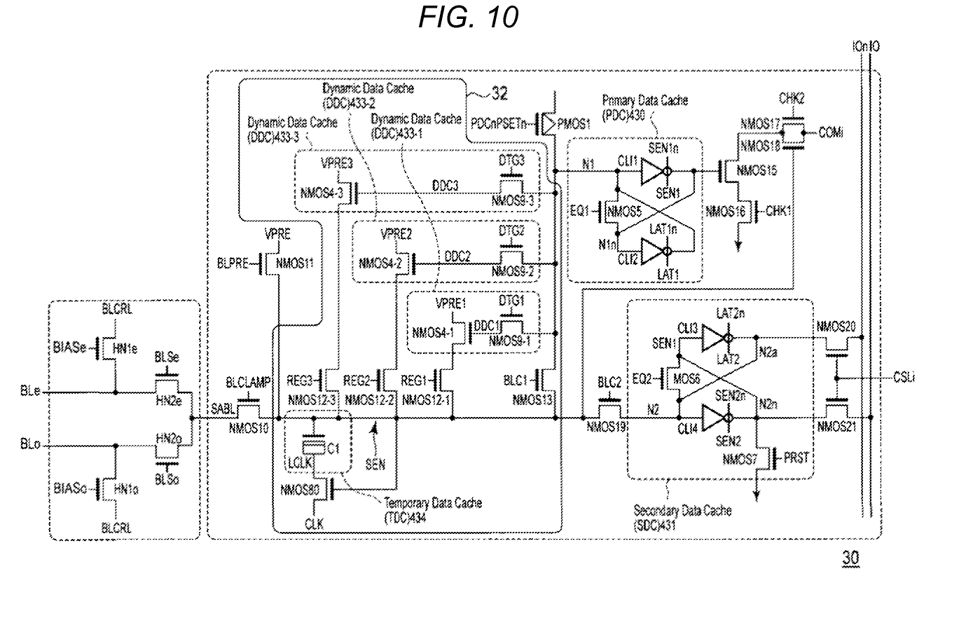

FIG. 10 is a circuit diagram illustrating a sense module 30 included in a sense circuit according to a fourth embodiment. A sense amplifier 32 included in the sense module 30 of the present embodiment is configured as a sense amplifier of a voltage sensing type.

In a current sensing type (ABL (all bit line) sensing type), data may be read simultaneously from all the bit lines. On the other hand, in a voltage sensing type, the potential of the bit line is fluctuated in accordance with read data, and such a potential fluctuation is detected by a sense transistor. A fluctuation in the potential of a certain bit line has an influence of the potential of an adjacent bit line due to capacitance coupling between bit lines. Therefore, in the voltage sensing type, unlike the current sensing type, data is read by shielding an adjacent bit line, for each even bit line and for each odd bit line (bit line shield method).

As illustrated in FIG. 10, the sense module 30 includes a sense amplifier 32, a primary data cache (PDC) 430, and a secondary data cache (SDC) 431. The sense amplifier 32 includes three dynamic data caches (DDC) 433 (433-1 to 433-3) and temporary data cache (TDC) 434. The dynamic data cache 433 and the temporary data cache 434 may be provided as necessary. The dynamic data cache 433 may also be used as a cache that holds data for writing a potential (VQPW) in the bit line, during a program. The potential (VQPW) is an intermediate potential between VDD (high potential) and VSS (low potential).

The primary data cache 430 includes clocked inverters CLI1 and CLI2 and a transistor NMOS5. The secondary data cache 431 includes clocked inverters CLI3 and CLI4 and transistors NMOS6 and NMOS7. The dynamic data cache 433 includes transistors NMOS4 and NMOS9. The temporary data cache 434 includes a capacitive element C1. The transistors NMOS4 to NMOS7, and NMOS9 are, for example, n-channel MOSFETs.

As described above, each of the primary data cache 430 and the secondary data cache 431 is configured as a flip-flop circuit including two clocked inverters. The transistor NMOS5 is an equalizer circuit that equalizes the potentials of two nodes N1 and N1n. The transistor NMOS6 is an equalizer circuit that equalizes the potentials of two nodes N2 and SEN1. Each of the transistors NMOS5 and NMOS6 is controlled by signals EQ1 and EQ2. The primary data cache 430 is controlled by signals SEN1, SEN1n, LAT1, and LAT1n. The secondary data cache 431 is controlled by signals SEN2, SEN2n, LAT2, and LAT2n. Here, “n” at the end of the signals SEN1n, LAT1n, SEN2n, and LAT2n means an inverted signal of a corresponding signal.

Transistors NMOS20 and NMOS21 are, for example, n-channel MOSFETs, and are column switches that determine electrical connection and disconnection between nodes N2a and N2n and input and output lines IO and IOn. When a column selection signal CSLi is set to be at an “H” level, the transistors NMOS20 and NMOS21 are turned on, and the output nodes N2a and N2n of the secondary data cache 431 are electrically connected to the input and output lines IO and IOn.

The circuit configurations of the primary data cache 430, the secondary data cache 431, the dynamic data cache 433, and the temporary data cache 434 are not limited to the circuit illustrated in FIG. 10, and may also adopt other circuit configurations. In addition, in the example of FIG. 10, the n-channel MOSFET is used as a transistor that controls the input and output of data in the data cache, but a p-channel MOSFET may be used.

The sense amplifier 32 includes transistors NMOS11, NMOS12 (12-1 to 12-3), and NMOS13, the node SEN as a first node, the node LCLK as a second node, and a transistor NMOS80. In addition, the sense amplifier 32 includes the transistors NMOS4 (4-1 to 4-3) and NMOS9 (9-1 to 9-3) within the dynamic data cache 433. Further, the sense amplifier 32 includes the capacitive element C1 within the temporary data cache 434. The transistors NMOS4, NMOS9, NMOS11 to NMOS13, and NMOS80 are, for example, n-channel MOSFETs.

The transistor NMOS11 is used for bit line precharge. That is, the transistor NMOS11 is a transistor that is controlled to precharge one bit line in which data is read, out of two bit lines BLe and BLo during reading. The transistor NMOS11 is controlled by a signal BLPRE. The transistors NMOS4, NMOS9, NMOS12, and NMOS13 controls odd or even page data during writing and reading (or during verify reading). In addition, the transistor NMOS12 checks whether writing or erasing is performed reliably on all the selected memory cells after verify reading, during writing and erasing.

When the memory cell is sensed, the node SEN is electrically connected to the bit lines BLe and BLo to be sensed. In addition, when the memory cell is sensed, the node SEN is set at a potential according to a potential on the bit lines BLe and BLo to be sensed.

The node LCLK is capacitively connected to the node SEN. That is, the node SEN and the node LCLK are connected to each other through the capacitive element C1.

The transistor NMOS80 receives the signal CLK in one end, is connected to the node LCLK at the other end, transfers the signal CLK to the node LCLK, and is connected to the node SEN at the gate. The transistor NMOS80 is turned on or turned off in accordance with the potential of the node SEN.

A transistor PMOS1 is a preset transistor that presets the node SEN to VDD. The transistor PMOS1 is, for example, a p-channel MOSFET, and is controlled by a signal PDCnPSETn.

A transistor NMOS10 is a clamp transistor that controls electrical connection and disconnection between the bit lines BLe and BLo and the sense amplifier 32. The transistor NMOS10 sets the bit lines BLe and BLo to be at a floating state, for example, during reading, until the bit lines BLe and BLo are precharged and then data which is read in the bit lines BLe and BLo is sensed. The transistor NMOS10 is, for example, an n-channel MOSFET, and is controlled by a signal BLCLMP.

The sense amplifier 32 is connected to the corresponding even bit line BLe and the corresponding odd bit line BLo, respectively, by transistors HN2e and HN2o. The transistors HN2e and HN2o are, for example, high voltage enhancement n-channel MOSFETs, and receive signals BLSe and BLSo, respectively, at the gates. In addition, one end of each of the transistors HN1e and HN10 is connected to each of the even bit line BLe and the odd bit line BLo. The transistors HN1e and HN10 are, for example, high voltage enhancement n-channel MOSFETs, receive signals BIASe and BIASo, respectively, at the gates, and receive a signal BLCRL at the other ends. The signal BLCRL is set at the potential VSS (ground potential, for example 0 V). when BIASo is set to be at an “H” level, and BIASe is set to be at an “L” level, data is read in the bit line BLe. The bit line BLo serves as a shield bit line for suppressing noise when data is read in the bit line BLe. When BIASe is set to be at an “H” level, and BIASo is set to be at an “L” level, data is read in the bit line BLo. The bit line BLe serves as a shield bit line for suppressing noise when data is read in the bit line BLo. In this manner, for example, during reading, one of two bit lines BLe and BLo serves as a bit line in which data is read, and the remaining one serves as a shield bit line.

(2) Operation of Sense Module

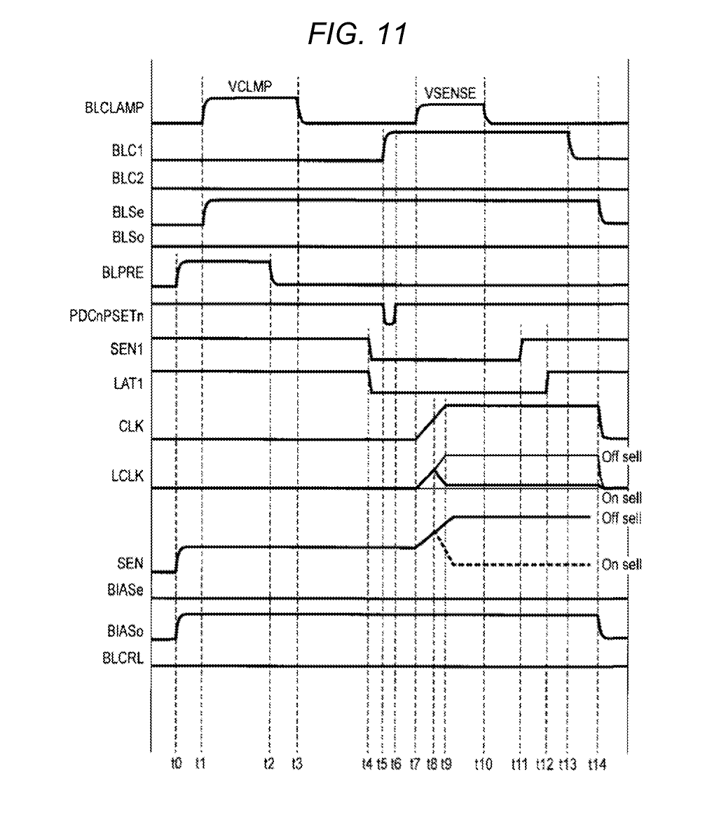

As illustrated in FIG. 11, at time t0, the core driver precharges a bit line to be read (even bit line BLe in the example of FIG. 11). Specifically, the core driver sets the signal BLPRE to be at an “H” level and turns on the transistor NMOS11, and thus precharges the even bit line BLe and the node SEN to the voltage VDD. In addition, the transistor 80 is turned on by the precharge of the node SEN. The precharge of the even bit line BLe is performed until time t2.

In addition, while the even bit line BLe is precharged, the core driver applies a clamp voltage VCLMP for bit line precharge to the transistor NMOS10 through a signal BLCLAMP. Specifically, the clamp voltage VCLMP continues to be applied to the transistor NMOS10 for a period between time t1 and time t3.

Next, for a period between time t0 and time t1, the core driver sets the signals BLSe and BLSo for bit line selection and the signals BIASe and BIASo for bias selection. In the example of FIG. 11, since the even bit line BLe is selected, the signal BLSe for even bit line selection is set to be at an “H” level. The signal BIASo is set to be at an “H” level, and the odd bit line BLo is fixed to BLCRL (=VSS). The states of the signals BLSe and BIASo are maintained until time t14.

Next, at time t3, the core driver sets the signal BLCLAMP at VSS. Thereby, the bit line BLe is set to be in an electrically floating state.

Next, at time t4, the core driver sets the signals SEN1 and LAT1 to be at an “L” level, and sets the clocked inverters CLI1 and CLI2 to be in an operation state. The signals SEN1 and LAT1 are maintained to be at an “L” level until time t11 and time t12, respectively.

Next, at time t5, the core driver applies a sensing voltage VSENSE2 to the transistor NMOS13 through a signal BLC1, and sets the signal PDCnPSETn to be at an “L” level. Thereby, the core driver precharges the node SEN to VDD. At time t6, the core driver sets the signal PDCnPSETn to be at an “H” level, and thus sets the temporary data cache 434 to be in a floating state. The signal BLC1 is maintained at the sensing voltage VSENSE2 until time t13.

Subsequently, for a period between time t7 and time t10, the core driver applies a sensing voltage VSENSE to the transistor NMOS10 based on of the signal BLCLAMP. In this case, when the potential of the selected bit line BLe is high, the transistor NMOS10 (transistor of BLCLAMP) is in a cutoff state, and VDD is held in the node SEN. On the other hand, when the potential of the selected bit line BLe is low, the transistor NMOS10 is turned on, and thus the node SEN is discharged and the potential thereof is substantially equal to the potential of the bit line BLe.

In addition, at time t7, the core driver starts a rise in the potential of the node SEN based on of the signal CLK. That is, when the signal CLK is set at a high potential, and the potential of the node LCLK is boosted. Since the transistor NMOS80 is turned on, the potential of the node SEN is also boosted through the capacitive element C1. The signal CLK continues to rise until time t9, and is also maintained at a high potential after time t9.

Thereby, the potential of the node SEN is discharged by a cell current flowing from the node SEN to the source line SL while being boosted along with a rise in the signal CLK. When the selected memory cell is turned on (thick lines), a relatively large current (on-current) flows from the node SEN to the source line SL. For this reason, the potential of the node SEN is maintained at a high potential until time t8, but thereafter, drops by the transistor NMOS80 being turned off. When the selected memory cell is turned off (thin lines), only a small current (off-current) flows from the node SEN to the source line SL. For this reason, the transistor 80 is not turned off, and the potential of the node SEN is also maintained at a high potential after time t8.

On the other hand, for a period between time t4 and time t12, the sensed data is incorporated into the primary data cache 430. As described above, the signal BLC1 is raised to the sensing voltage VSENSE2 in a state where the potential charged for a period between time t1 and time t2 remains in the node SEN. When the potential of the node SEN is higher than a difference (VSENSE2−Vth) between the sensing voltage VSENSE2 and the threshold voltage Vth of the transistor NMOS13, the transistor NMOS13 is not turned on. For this reason, data of the temporary data cache 434 is transferred to the primary data cache 430, and data of the primary data cache 430 is set to “1”. In addition, when the potential of the node SEN is lower than a difference (VSENSE2−Vth) between the sensing voltage VSENSE2 and the threshold voltage Vth of the transistor NMOS13, the data of the primary data cache 430 is set to “0”.

As described above, data is read from the even bit line BLe. The same procedure is also used in the reading of the odd bit line BLo. In this case, reversely to the example of FIG. 11, a signal BLDo is set to be at an “H” level, and the signal BLSe is set to be at VSS. In addition, the signal BIASe is set to be at an “H” level, and the signal BIASo is set to be at VSS.

As described above, in an example in which the sense amplifier 32 of a voltage sensing type is used, it is possible to increase an on/off ratio during data reading.

### Other Embodiments

As described above, while respective embodiments and modification examples have been described, the embodiments and the like have been presented by way of example only, and the technical idea of the embodiments and the like does not limit materials, shapes, structures, layouts and the like of components. The new embodiments and the like may be embodied in a variety of other forms, and various omissions, substitutions, and changes may be made without departing from the spirit of the embodiments in the implementation phase. Further, various steps are included in the embodiments and the like, and various embodiments may be extracted by an appropriate combination of a plurality of components disclosed.

Each functional block may be achieved by any of hardware and computer software, or a combination of both. Therefore, as it is clear that each functional block is present in any of the hardware and computer software, the above description is given generally from the viewpoint of the functions. Those skilled in the art may realize the functions using various methods for each specific embodiment, but any of the realization methods is also included in the scope of the embodiments. In addition, it is not essential that the respective functional blocks be distinguished from each other as in the aforementioned examples. For example, a portion of the functions may be executed by separate functional blocks from the illustrated functional blocks. The illustrated functional blocks may be divided into more specific functional sub-blocks. The embodiments are not limited depending on specification by any of the functional blocks.

In the above-mentioned embodiments and the like, an example is described in which the node SEN is charged based on of the signal HLL from the transistor 64, but there is no limitation thereto. For example, the node SEN may be charged based on of the signal BLQ instead of the signal HLL. Specifically, at time t1 of FIG. 5 stated above, the core driver 14 sets to the signal BLQ to be at an “H” level (voltage VH), and sets the signal PCn to be at an “L” level (VSS). Thereby, the transistors 24 and 65 are turned on, and the node SEN is charged to VDD through the node LBUS and the transistor 65.

In the above-mentioned embodiments and the like, an example is described in which the memory string 19 is configured as a structure having a plurality of memory cells connected to each other, but the structure of the memory string 19 is not limited thereto. The memory string may be configured as a structure having a plurality of memory cells connected in series through a back gate transistor.

Besides, the configuration of the memory cell array may have the one disclosed in, for example, U.S. Patent Application Publication No. 2009/0267128 (U.S. patent application Ser. No. 12/407,403) entitled “THREE DIMENSIONAL STACKED NONVOLATILE SEMICONDUCTOR MEMORY”. In addition, the configuration may have the one disclosed in U.S. Patent Application Publication No. 2009/0268522 (U.S. patent application Ser. No. 12/406,524) entitled “THREE DIMENSIONAL STACKED NONVOLATILE SEMICONDUCTOR MEMORY”, U.S. Patent Application Publication No. 2010/0207195 (U.S. patent application Ser. No. 12/679,991) entitled “NON-VOLATILE SEMICONDUCTOR STORAGE DEVICE AND METHOD OF MANUFACTURING THE SAME”, and U.S. Patent Application Publication No. 2011/0284946 (U.S. patent application Ser. No. 12/532,030) entitled “SEMICONDUCTOR MEMORY AND METHOD FOR MANUFACTURING THE SAME”. The patent applications are incorporated in this disclosure by reference in their entireties.

In the above-mentioned embodiments and the like, the storage system of the memory cell may be a binary storage system, a multi-valued memory system, and the like. Examples of a read operation, a write operation, and an erase operation in the memory cell of the multi-valued memory system will be described below in detail.

For example, in a multi-level read operation, a threshold voltage is set to an A level, a B level, a C level, and the like, in order of increasing voltage. In such a read operation, a voltage which is applied to a word line selected in the read operation of the A level is, in the range of, for example, 0 V to 0.55 V. The voltage may be in any range of 0.1 V to 0.24 V, 0.21 V to 0.31 V, 0.31 V to 0.4 V, 0.4 V to 0.5 V, 0.5 V to 0.55 V, and the like, without being limited thereto. A voltage which is applied to a word line selected in the read operation of the B level is in the range of, for example, 1.5 V to 2.3 V. The voltage may be in any range of 1.65 V to 1.8 V, 1.8 V to 1.95 V, 1.95 V to 2.1 V, 2.1 V to 2.3 V, and the like, without being limited thereto. A voltage which is applied to a word line selected in the read operation of the C level is in the range of, for example, 3.0 V to 4.0 V. The voltage may be in any of range of 3.0 V to 3.2 V, 3.2 V to 3.4 V, 3.4 V to 3.5V, 3.5V to 3.6V, 3.6V to 4.0 V, and the like, without being limited thereto. A time (tR) of the read operation may be in any range of, for example, 25 μs to 38 μs, 38 μs to 70 μs, 70 μs to 80 μs, and the like.

The write operation includes a program operation and a verify operation. In the write operation, a voltage which is initially applied to a word line selected during the program operation is in the range of, for example, 13.7 V to 14.3 V. The voltage may be in any of, for example, 13.7 V to 14.0 V, 14.0 V to 14.6 V, and the like, without being limited thereto. A voltage which is initially applied to the selected word line during writing of odd-numbered word lines and a voltage which is initially applied to the selected word line during writing of even-numbered word lines may be set to be different from each other. When the program operation is set to an ISPP (Incremental Step Pulse Program) system, a step-up voltage includes, for example, approximately 0.5 V. A voltage which is applied to a non-selected word line may be in the range of, for example, 6.0 V to 7.3 V. The voltage may be in the range of, for example, 7.3 V to 8.4 V without being limited thereto, and may be equal to or less than 6.0 V. Pass voltages to be applied may be set to be different from each other depending on whether the non-selected word line is an odd-numbered word line or an even-numbered word line. A time (tProg) of the write operation may be in the range of, for example, 1700 μs to 1800 μs, 1800 μs to 1900 μs, and 1900 μs to 2000 μs.

In the erase operation, a voltage which is initially applied to a well, formed on the semiconductor substrate, which has a memory cell disposed thereon is in the range of, for example, 12 V to 13.6 V. The voltage may be in any range of, for example, 13.6 V to 14.8 V, 14.8 V to 19.0 V, 19.0 V to 19.8 V, 19.8 V to 21 V, and the like, without being limited thereto. The time (tErase) of the erase operation may be in the range of, for example, 3,000 μs to 4,000 μs, 4,000 μs to 5,000 μs, and 4,000 μs to 9,000 μs.

In addition, the above-mentioned embodiments and the like may also be applied to a flat NAND type flash memory. The flat NAND type flash memory is a NAND type flash memory having memory cells disposed on a flat surface. In this case, the memory cell may have, for example, the following structure.

The memory cell includes a charge storage film which is disposed on a semiconductor substrate such as a silicon substrate through a tunnel insulating film having a thickness of 4 nm to 10 nm. This charge storage film may be formed to have a stacked structure of an insulating film such as a silicon nitride (SiN) film or a silicon oxynitride (SiON) film having a thickness of 2 nm to 3 nm, and a polysilicon (Poly-Si) film having a thickness of 3 nm to 8 nm. A metal such as ruthenium (Ru) may be added to the polysilicon film. The memory cell includes an insulating film on the charge storage film. The insulating film includes a silicon oxide (SiO₂) film having a thickness of 4 nm to 10 nm which is interposed between a lower-layer High-k film having, for example, a thickness of 3 nm to 10 nm and an upper-layer High-k film having a thickness of 3 nm to 10 nm. Materials of the High-k film include hafnium oxide (HfO) and the like. In addition, the thickness of the silicon oxide film may be made to be larger than the thickness of the High-k film. A control electrode having a thickness of 30 nm to 70 nm is provided on the insulating film through a work function adjusting film having a thickness of 3 nm to 10 nm. Here, the film is, for example, a metal oxide film such as tantalum oxide (TaO), a metal nitride film such as tantalum nitride (TaN), or the like. Tungsten (W) or the like may be used in the control electrode. An air gap may be disposed between the memory cells.

### APPENDICES

Hereinafter, preferred aspects of the embodiments are appended.

### Appendix 1

According to an aspect of the embodiment, there is provided a semiconductor memory device including:

a memory cell;

a bit line that is electrically connected to the memory cell;

a first node that is electrically connected to the bit line;

a capacitive element that is connected to the first node;

a second node that is connected to the capacitive element; and

a transistor that receives a signal at one end, transfers the signal to the second node connected to another end, and having a gate connected to the first node.

### Appendix 2

According to another aspect of the embodiment, there is provided a semiconductor memory device including:

a memory cell;

a bit line that is electrically connected to the memory cell;

a first node that is electrically connected to the bit line;

a first transistor in which the first node is connected to a gate;

a capacitive element that is connected to the first node;

a second node that is connected to the capacitive element; and

a second transistor that receives a signal at one end, transfers the signal to the second node connected to the other end, and having a gate connected to the first node.

While certain embodiments have been described, the embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell;
a bit line that is electrically connected to the memory cell;
a first node that is electrically connected to the bit line;
a capacitive element having a first end electrically connected to the first node and a second end electrically connected to a second node; and
a transistor having a gate electrically connected to the first node, a first end, and a second end, the second end being electrically connected to the second node.

2. The device according to claim 1, wherein the transistor transfers a potential from the first end thereof to the second end thereof when a potential difference between the first node and the first end is equal to or greater than a threshold voltage of the transistor, and blocks the transfer of a potential from the first end thereof to the second end thereof when the potential difference between the first node and the first end is less than the threshold voltage of the transistor.

3. The device according to claim 2, wherein
the potential of the first end rises during a sensing operation performed on the memory cell.

4. The device according to claim 3, wherein
during the sensing operation, the first node is discharged at a discharging rate varying in accordance with an on-off state of the memory cell.

5. The device according to claim 4, wherein
the transistor is maintained to be turned on when the discharging rate of the first node decreases, and a potential difference between the first node and the first end is maintained to be equal to or greater than the threshold voltage of the transistor, and
the transistor is turned off when the discharging rate of the first node decreases, and the potential difference between the first node and the first end is less than the threshold voltage of the transistor.

6. The device according to claim 3, wherein
the potential of the first end remains constant after sensing of the memory cell.

7. The device according to claim 3, wherein
the potential of the second end of the transistor is increased along with the first end of the transistor before the sensing operation on the memory cell.

8. A semiconductor memory device comprising:
a memory cell;
a bit line that is electrically connected to the memory cell; and
a sense module electrically connected to the bit line and configured to detect data stored in the memory cell based on a current flow through the bit line, wherein the sense module includes a sense node, a capacitive element having a first end electrically connected to the sense node and a second end electrically connected to a transistor,
the transistor having a gate electrically connected to the sense node, a first end, and a second end, the second end being electrically connected to the second end of the capacitive element.

9. The device according to claim 8, wherein the transistor transfers a potential from the first end thereof to the second end thereof when a potential difference between the sense node and the first end is equal to or greater than a threshold voltage of the transistor, and blocks the transfer of the potential from the first end thereof to the second end thereof when the potential difference between the sense node and the first end is less than the threshold voltage of the transistor.

10. The device according to claim 9, wherein
the potential of the first end rises during a sensing operation performed on the memory cell.

11. The device according to claim 10, wherein
during the sensing operation, the first node is discharged at a discharging rate varying in accordance with an on-off state of the memory cell.

12. The device according to claim 11, wherein
the transistor is maintained to be turned on when the discharging rate of the sense node decreases, and a potential difference between the sense node and the first end is maintained to be equal to or greater than the threshold voltage of the transistor, and
the transistor is turned off when the discharging rate of the sense node decreases, and the potential difference between the sense node and the first end is less than the threshold voltage of the transistor.

13. The device according to claim 10, wherein
the potential of the first end remains constant after sensing of the memory cell.

14. The device according to claim 10, wherein
the potential of the second end of the transistor is increased along with the first end of the transistor before the sensing operation on the memory cell.

15. A method of performing a sensing operation in a semiconductor memory device having a memory cell, a bit line that is electrically connected to the memory cell, and a sense module electrically connected to the bit line and configured to detect data stored in the memory cell based on a current flow through the bit line, wherein the sense module includes a sense node, a capacitive element having a first end electrically connected to the sense node and a second end electrically connected to a transistor having a gate that is electrically connected to the sense node, a first end electrically connected to a potential source and a second end electrically connected to the second end of the capacitive element, said method comprising:
applying a potential from the potential source to the first end of the transistor; and
turning on the transistor to transfer the potential from the first end thereof to the second end thereof and turning off the transistor to block the transfer of the potential from the first end thereof to the second node thereof.

16. The method according to claim 15, wherein the transistor is turned on when a potential difference between the sense node and the applied potential is equal to or greater than a threshold voltage of the transistor, and is turned off when the potential difference between the sense node and the applied potential is less than the threshold voltage of the transistor.

17. The device according to claim 16, wherein
the potential is continued to be applied from the potential source to the first end of the transistor even after sensing of the memory cell.

18. The device according to claim 16, wherein
the potential is applied from the potential source to the first end of the transistor before the sensing operation on the memory cell has started.
